(19) United States
(12) Patent Application Publication
(10) Pub. No.: US 2009/0057786 A1
(43) Pub. Date: Mar. 5, 2009

(54) SEMICONDUCTOR DEVICE AND METHOD OF MANUFACTURING SEMICONDUCTOR DEVICE

(75) Inventor: Katsuhiko Fukasaku, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/197,388

(22) Filed: Aug. 25, 2008

(30) Foreign Application Priority Data
Aug. 30, 2007 (JP) 2007-223761

(51) Int. Cl. H01L 29/78; H01L 21/28

(52) U.S. Cl. 257/410; 438/591; 257/E21.177; 257/E29.255

(57) ABSTRACT

A semiconductor device includes a high dielectric constant gate insulator film provided on a Si substrate which is a semiconductor substrate, a gate electrode formed on the high dielectric constant gate insulator film, a protective film provided on side surfaces of the high dielectric constant gate insulator film and the gate insulator, and a side wall film provided on the outside of the protective film. The protective film includes a high dielectric constant material having, in its composition, at least one metal selected from the group consisting of Hf, Zr, Al, La, Pr, Y, Ti, Ta and W, whereby it is possible to suppress the causes of such troubles as dispersions of characteristics and deterioration of short channel characteristic.

### CROSS REFERENCES TO RELATED APPLICATIONS

The present invention contains subject matter related to Japanese Patent Application JP 2007-223761 filed in the Japan Patent Office on Aug. 30, 2007, the entire contents of which being incorporated herein by reference.

### BACKGROUND OF THE INVENTION

1. Field of the Invention

The present invention relates to a semiconductor device using a high dielectric constant gate insulator film and a method of manufacturing a semiconductor device.

2. Description of the Related Art

A CMOS (Complementary Metal Oxide Semiconductor) circuit configured by forming an N-type MOSFET and a P-type MOSFET on the same substrate is widely used as a component device of many LSIs, in view of its small power consumption and easiness in enhancing the fineness and the degree of integration which promises a higher-speed operation.

In the related art, a thermal oxide film (SiO₂) of silicon (Si) or a film (SiON) obtained by nitriding the thermal oxide film under heating or in plasma has been used for a gate insulator film, and, as for gate electrodes, phosphorus-doped or arsenic-doped n-type poly-Si and boron-doped p-type poly-Si have been widely used for n-type FETs and p-type FETs, respectively.

However, in the case of thinning the gate insulator film and/or shortening the gate length according to the scaling rule, the thinning of a SiO₂ film or a SiON film would be attended by an increased gate leak current or a lowered reliability, and depletion generated in the gate electrode would lead to a lowered gate capacity or the like trouble. In view of this, insulating materials having high dielectric constants (high dielectric constant films) are used for the gate insulator film.

Besides, it is known that, in a gate insulator film using a high dielectric constant material, a threshold variation occurs at the sides of the gate insulator film, leading to a peculiar behavior in the short channel region and to dispersions of device characteristics (refer to Toshiyuki Iwamoto et al., “A Highly Manufacturable Low Power and High Speed HfSiO CMOS FET with Dual Poly-Si Gate Electrodes”, IEEE, 2003, IEDM (International Electron Device Meeting) Technical Digest, p. 639 (hereinafter referred to as Non-patent Document 1)).

Here, Non-patent Document 1 proposes a model in which penetration of oxygen through side walls cause a variation in the EOT (Equivalent Oxide Thickness) at the sides of the gate insulator film. In addition, a problem in the structure using a high dielectric constant material for the gate insulator film is proposed as a model in which fixed charges are introduced into the gate side walls (refer to Takeshi Watanabe et al., “Impact of Hf Concentration on Performance Reliability for HfSiON-CMOSFET”, IEEE, 2004, IEDM Technical Digest, p. 507).

In each of the above-mentioned documents, what matters is the problem of the layout dependency in regard of variations of threshold in the short channel region. From this point of view, Non-patent Document 1 presents an idea of a structure in which an oxide film or the like is used at the gate side walls so as to prevent introduction of the fixed charges. Furthermore, Japanese Patent Laid-open No. 2006-93670 proposes a structure in which a nitride film is introduced to the side walls so as to suppress diffusion of oxygen.

### SUMMARY OF THE INVENTION

However, in the case of the structure in which the nitride film is laminated on side surfaces of the gate insulator film and the gate electrode, processing of the nitride film after formation thereof causes digging (hollowing) of the silicon substrate. The digging, in turn, causes such troubles as dispersions of device characteristics and deterioration of short channel characteristic which would arise from approaching of source/drain extension regions toward the channel region due to depression of the silicon substrate. In addition, the use of the nitride film as the side wall material would shorten the distance between the adjacent gate electrodes, thereby reducing the process margins for the subsequent side wall formation and processing between the gate electrodes.

Thus, there is a need to solve the above-mentioned problems.

In accordance with an embodiment of the present invention, there is provided a semiconductor device including: a high dielectric constant gate insulator film provided on a semiconductor substrate; a gate electrode formed on the high dielectric constant gate insulator film; a protective film formed at side walls of the high dielectric constant gate insulator film and the gate electrode; and a side wall material provided on the outside of the protective film. The protective film includes a high dielectric constant material having, in its composition, at least one metal selected from the group consisting of Hf, Zr, Al, La, Pr, Y, Ti, Ta and W.

In the semiconductor device according to an embodiment of the present invention, the concentration of the metal is in the range of from 1×10¹³ atoms/cm², inclusive, to 1×10¹⁵ atoms/cm², exclusive.

In the embodiment of the present invention, the protective film including the high dielectric constant material is disposed at the side surfaces of the gate electrode and the high dielectric constant gate insulator film, so that diffusion of oxygen into the high dielectric constant gate insulator film can be inhibited. Therefore, variations in characteristics such as a change in the EOT at gate ends can be prevented from being caused. In addition, to form a nitride film on side surfaces of the gate electrode and the high dielectric constant gate insulator film and to process the nitride film are unnecessary, so that digging of the semiconductor substrate which would occur during such a processing is obviated.

Here, the high dielectric constant material is a so-called high-k material in the semiconductor technology, and principally means a material having a dielectric constant higher than that of SiO₂.

In the above-mentioned embodiment of the invention, preferably, side ends of the high dielectric constant gate insulator film are provided on the inner side relative to side ends of the gate electrode, and the thickness of the protective film (high dielectric constant material) at the side surfaces of the high dielectric constant gate insulator film is greater than the thickness of the protective film (high dielectric constant material) at the side surfaces of the gate electrode.

This ensures that the composition of the high dielectric constant material beside the gate insulator film and the composition of the high dielectric constant material on the semiconductor substrate can be set different. Therefore, a process design for suppressing diffusion of oxygen into the gate insulator film and a process design for eliminating the high dielectric constant material present on the semiconductor substrate can be set separately.

In accordance with another embodiment of the present invention, there is provided a method of manufacturing a semiconductor device, including the steps of: forming a high dielectric constant gate insulator film and a gate electrode with predetermined lengths on a semiconductor substrate; and forming a protective film containing at least one metal selected from the group consisting of Hf, Zr, Al, La, Pr, Y, Ti, Ta and W, at side surfaces of the high dielectric constant gate insulator film and the gate electrode. The method further includes the steps of: depositing a side wall material on the outside of the protective film and simultaneously oxidizing the metal to convert the metal into a high dielectric constant material; and etching the high dielectric constant material together with the side wall material to form a side wall including the side wall material at the side surfaces of the high dielectric constant gate insulator film and the gate electrode, with the high dielectric constant material therebetween.

In the method of manufacturing a semiconductor device according to another embodiment of the present invention, after the formation of the high dielectric constant gate insulator film and the gate electrode, side ends of the high dielectric constant gate insulator film are processed to be on the inner side relative side ends of the gate electrode, and subsequently the high dielectric constant material is formed.

In this embodiment of the present invention, the protective film having at least one metal selected from the group consisting of Hf, Zr, Al, La, Pr, Y, Ti, Ta and W (the film containing the metal for forming the high dielectric constant material) is disposed at the side surfaces of the gate electrode and the high dielectric constant gate insulator film. Therefore, the metal in the protective film can be converted into the high dielectric constant material by oxidation in the subsequent step of depositing the side wall material, whereby diffusion of oxygen into the high dielectric constant gate insulator film can be inhibited. As a result, variations in characteristics such as a change in the EOT at gate ends can be prevented from being caused. In addition, to form a nitride film on side surfaces of the gate electrode and the high dielectric constant insulator film and to process the nitride film are unnecessary, and, therefore, digging of the semiconductor substrate which would occur during such a processing can be obviated.

The present invention has the following effects. In the semiconductor device using a high dielectric constant gate insulator film, it is possible to suppress the causes of such troubles as dispersions of device characteristics and deterioration of short channel characteristic. Besides, it is possible to provide a structure in which it is unnecessary to process the side wall material for the high dielectric constant gate insulator film and the gate electrode and it is unnecessary to shorten the space between the gate electrodes.

### BRIEF DESCRIPTION OF THE DRAWINGS

FIG. 1 is a schematic sectional view for illustrating the structure of a semiconductor device according to an embodiment of the present invention;

FIG. 2 is a schematic sectional view (No. 1) for sequentially illustrating a semiconductor device manufacturing method (No. 1) according to an embodiment of the present invention;

FIG. 3 is a schematic sectional view (No. 2) for sequentially illustrating the semiconductor device manufacturing method (No. 1) according to the embodiment of the present invention;

FIG. 4 is a schematic sectional view for sequentially illustrating the semiconductor device manufacturing method (No. 1) according to the embodiment of the present invention;

FIG. 5 is a schematic sectional view (No. 3) for sequentially illustrating the semiconductor device manufacturing method (No. 1) according to the embodiment of the present invention;

FIG. 6 is a schematic sectional view (No. 4) for sequentially illustrating the semiconductor device manufacturing method (No. 1) according to the embodiment of the present invention;

FIGS. 7A and 7B are schematic sectional views for sequentially illustrating the semiconductor device manufacturing method (No. 1) according to the embodiment of the present invention;

FIG. 8 is a schematic sectional view (No. 5) for sequentially illustrating the semiconductor device manufacturing method (No. 1) according to the embodiment of the present invention;

FIG. 9 is a schematic sectional view (No. 1) for sequentially illustrating a semiconductor device manufacturing method (No. 2) according to an embodiment of the present invention;

FIG. 10 is a schematic sectional view (No. 2) for sequentially illustrating the semiconductor device manufacturing method (No. 2) according to the embodiment of the present invention; and

FIG. 11 is a schematic sectional view for illustrating the structure of the semiconductor device manufactured by the semiconductor device manufacturing method (No. 2) according to the embodiment of the present invention.

### DETAILED DESCRIPTION OF THE PREFERRED EMBODIMENTS

Now, some embodiments of the present invention will be described below, based on the drawings.

### <Structure of Semiconductor Device>

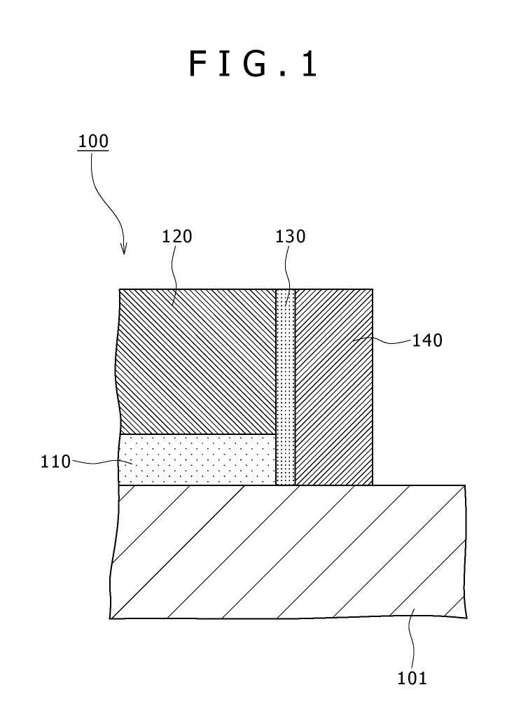

FIG. 1 is a schematic sectional view for illustrating the structure of a semiconductor device according to an embodiment of the present invention. The semiconductor device 100 according to the embodiment relates mainly to an n-type FET and a p-type FET in a CMOS semiconductor device, and includes a high dielectric constant gate insulator film 110 provided on a Si (silicon) substrate 101 serving as a semiconductor substrate, a gate electrode 120 formed on the high dielectric constant gate insulator film 110, protective films 130 provided at side surfaces of the high dielectric constant gate insulator film 110 and the gate electrode 120, and side wall films 140 provided on the outside of the protective films 130.

Especially, in this embodiment, a high dielectric constant material having at least one metal selected from the group consisting of Hf, Zr, Al, La, Pr, Y, Ti, Ta and W in its composition is used to form the protective film 130.

Here, the high dielectric constant material is a so-called high-k material in the semiconductor technology, and principally means a material having a dielectric constant higher than that of SiO₂. The high dielectric constant material is an oxidized material having at least one metal selected from the group consisting of Hf, Zr, Al, La, Pr, Y, Ti, Ta and W in its composition. In this embodiment, HfSiON is used as a material for the high dielectric constant gate insulator film 110, and HfSiOx is used as a material for the protective film 130. Incidentally, while an example in which the above-mentioned high dielectric constant materials are used is described in this embodiment, the present invention is not limited to this example.

In the semiconductor device 100 according to this embodiment as above, the protective films 130 including a high dielectric constant material are disposed at the side surfaces of the gate electrode 120 and the high dielectric constant gate insulator film 110, so that diffusion of oxygen into the high dielectric constant gate insulator film 110 can be inhibited. In addition, since the high dielectric constant material instead of a nitride film is used for the protective films 130, the processing needed in the case where the nitride film is formed is unnecessary, and digging of the Si substrate 101 ordinarily caused during such a processing is obviated. The digging of the Si substrate 101, if occurred, would increase the parasitic resistance in source/drain extension regions, causing dispersions in characteristics. In this embodiment, the protective films 130 can be made to function, without causing such digging of the Si substrate 101, so that the characteristics of the semiconductor device 100 using the high dielectric constant gate insulator film 110 can be made stable.

### <Semiconductor Device Manufacturing Method (No. 1)>

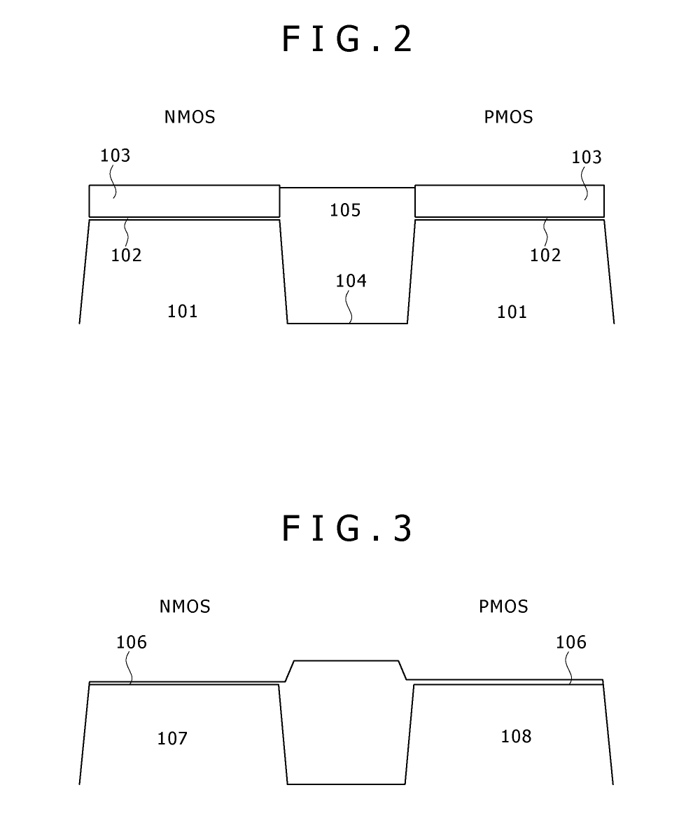

Now, a method of manufacturing a semiconductor device according to this embodiment of the present invention will be described below. FIGS. 2 to 8 are schematic sectional views for sequentially illustrating the semiconductor device manufacturing method (No. 1) according to this embodiment. Now, description will be made following the sequence of steps.

(a) Device Isolation Forming Step (No. 1) (FIG. 2)

After SiO₂ 102 and Si₃N₄ 103 are deposited on a Si (silicon) substrate 101, resist patterning is applied to a portion where an active region is to be formed, and, using the patterned resist as a mask, Si₃N₄ and SiO₂ and the Si substrate are sequentially etched to form a groove (trench region) 104.

In this case, the Si substrate 101 is etched to a depth of 350 to 400 nm, for example. Here, the Si₃N₄ pattern region becomes an active region, and the trench region becomes a field oxide film.

Thereafter, the groove (trench region) 104 is filled up with SiO₂ 105. For example, the filling is conducted by high-density plasma CVD (Chemical Vapor Deposition), whereby it is possible to form a film being good in step coverage and denseness. Subsequently, polishing is conducted by CMP (Chemical Mechanical Polish), for flattening (planarization). In this case, the polishing is carried out to such an extent that, in the Si₃N₄ boundary regions, the SiO₂ film on Si₃N₄ can be removed.

(b) Device Isolation Forming Step (No. 2) (FIG. 3)

Removal of Si₃N₄ 103 (see FIG. 5) is conducted by using, for example, hot phosphoric acid, whereby an active region is formed. Subsequently, the surface of the active region is oxidized to form an oxide film 106 having a thickness of 10 nm, for example. Next, a region where to form an NMOSFET is subjected to formation of a P-type well region, ion implantation for forming a buried layer for the purpose of inhibiting punch-through in MOSFET, and ion implantation for Vth regulation, to form an NMOS channel region 107. On the other hand, a region where to form a PMOSFET is subjected to formation of an N-type well region, ion implantation for forming a buried layer for the purpose of inhibiting punch-through in MOSFET, and ion implantation for Vth regulation, to form a PMOS channel region 108.

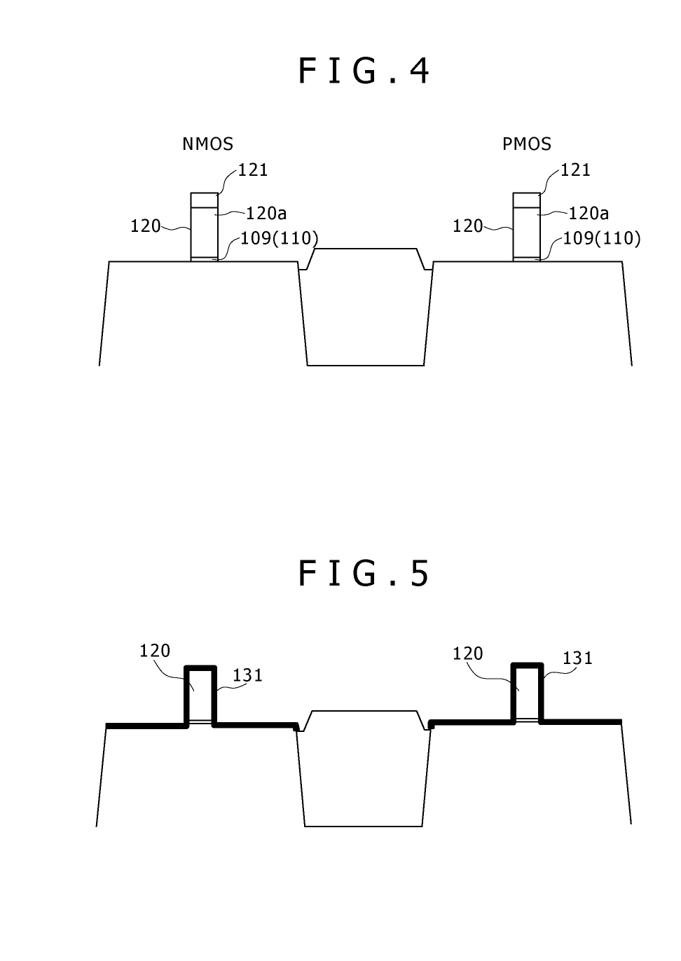

(C) Gate Electrode Forming Step (FIG. 4)

After the above-mentioned sacrificing oxide film is peeled by use of a hydrofluoric acid solution, dry oxidation (O₂, 700° C.) is performed to form a gate oxide film 109 in a thickness of about 1.5 to 2.0 nm. As the oxidizing gas here, not only dry O₂ but also gaseous mixtures such as H₂/O₂, N₂O and NO, etc. can be used. Besides, not only a furnace but also RTA (Rapid Thermal Anneal) can be used. In addition, doping of the oxide film with nitrogen by a plasma nitriding technique can also be used. Further, in this case, for example by separately forming gate oxide films having different thicknesses of 3 nm and 5 nm, MOSFETs differing in applied voltage or threshold voltage can be separately formed in the substrate surface.

Next, a material, for example hafnium, for forming the high dielectric constant material is deposited in a concentration of 1×10¹⁴ atoms/cm² by a PVD (Physical Vapor Deposition) method. Thereafter, annealing is conducted in a nitrogen atmosphere, to increase the bonding strength between hafnium and the oxide film 109. As a result, the high dielectric constant gate insulator film 110 including HfSiON is produced.

Then, poly-Si 120a is deposited in a thickness of 100 to 150 nm by low pressure CVD (for example, using SiH₄ as a raw material gas, at a deposition temperature of 580 to 620° C.). Subsequently, Si₃N₄ 121 is deposited as a hard mask in a thickness of, for example, 50 to 100 nm by LP-CVD. Then, resist patterning is conducted by lithography, and, with the resist as a mask, anisotropic etching is carried out to form gate electrodes 120. In this case, after the resist patterning, a trimming treatment or the like may be conducted using an O₂ plasma, thereby reducing the horizontal size of the gate electrodes 120; for example, in the 65 nm-node technology CMOS, the gate length can be made to be about 30 nm.

(D) Gate Side Wall Treating Step (FIG. 5)

A material, for example hafnium, for forming a high dielectric constant material over the whole surface of the substrate provided with the gate electrodes 120 is deposited in a concentration of 5×10¹³ atoms/cm² by PVD. Then, annealing is conducted in an NH₃ atmosphere, to increase the bonding strength between hafnium 131 and the sides of the gate insulator film material.

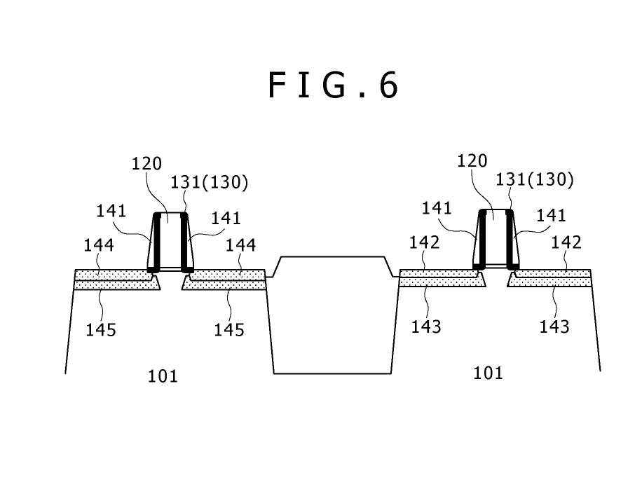

(E) MOSFET Forming Step (FIG. 6)

Subsequently, for forming offset spacers, TEOS (Tetraethyl orthosilicate) oxide films 141 are deposited in a thickness of, for example, about 8 nm by CVD. By the oxygen used as a carrier gas during the oxide film CVD, hafnium 131 at the sides of the gates is converted into the high dielectric constant material (protective films 130) having a composition of HfSiOx.

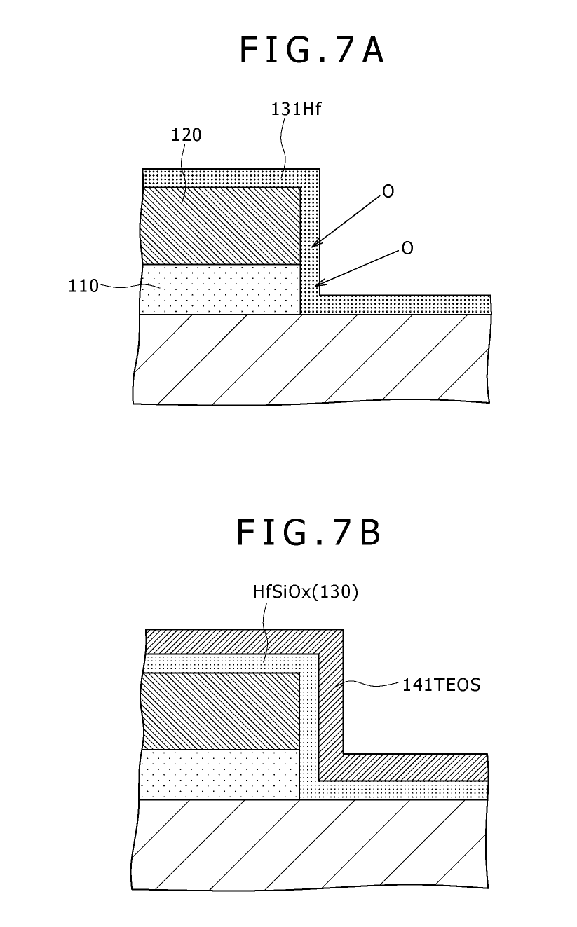

FIGS. 7A and 7B are schematic sectional views for illustrating the condition in which hafnium at the sides of the gates becomes a high dielectric constant material. As shown in FIG. 7A, in the condition where hafnium 131 is so formed as to cover the gate electrode 120 and the high dielectric constant gate insulator film 110, the subsequent step is conducted to form the TEOS oxide film 141 by CVD, when oxygen used as a carrier gas diffuses into hafnium 131. Then, as shown in FIG. 7B, at the time when the TEOS oxide film 141 is formed, hafnium 131 is oxidized to become the high dielectric constant material (protective film 130) having a composition of HfSiOx.

Next, the TEOS oxide film 141 is subjected to anisotropic etching by RIE (Reactive Ion Etching) to form an offset spacer at the gate electrode 120 (see FIG. 6). By the RIE in this instance, HfSiOx on the Si substrate 101 is eliminated substantially completely. That is, simultaneously with the etching of the TEOS oxide film 141, hafnium 131 on the gate electrode 120 and the Si substrate 101 is removed. This eliminates a step of etching hafnium 131 singly, so that digging of the silicon substrate 101 during such etching can be obviated.

Thereafter, BF₂⁺ ions are implanted into the PMOS region under the conditions of 2 keV and 1.5×10¹⁵/cm² to form LDD regions 142, and As ions are implanted under the condition of 50 keV and 2.5×10¹³/cm² to form pocket regions 143.

Besides, As⁺ ions are implanted into the NMOS region under the conditions of 5 keV and 1.5×10¹⁵/cm² to form LDD regions 144, and BF₂ ions are implanted under the conditions of 35 keV and 3×10¹³/cm² to form pocket regions 145. In addition, it is possible, by performing the ion implantations after the formation of the offset spacers, to suppress the short channel effect and to reduce dispersions of MOSFET characteristics.

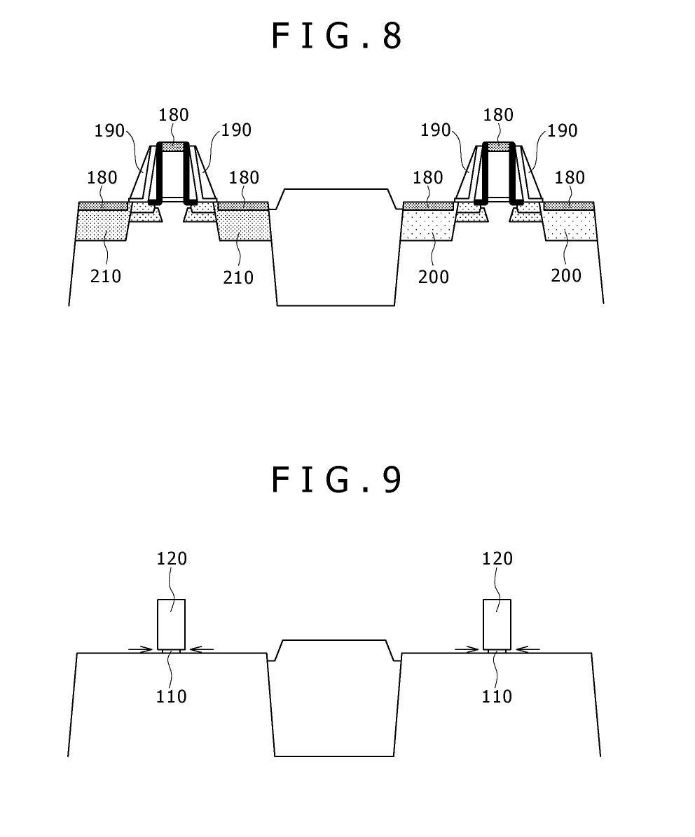

(F) MOSFET Forming and Silicide Forming Step (FIG. 8)

After Si₃N₄ 180 is deposited in a thickness of 50 to 70 nm by CVD, and SiO₂ 190 is deposited in a thickness of 50 to 70 nm by CVD, to form an insulator film for side walls. Subsequently, anisotropic etching is conducted, to form the side walls at the gate electrodes.

Next, B ions are implanted into the PMOS region under the conditions of 2 keV and 3×10¹⁵/cm² to form P-type source/drain regions 200; then, As ions are implanted into the NMOS region under the conditions of 20 keV and 2×10¹⁵/cm² and P ions are implanted under the conditions of 7 keV and 5×10¹⁴/cm², to form N-type source/drain regions 210.

Thereafter, activation of impurities is conducted by RTA (Rapid Thermal Annealing) under the conditions of 1000° C. and 5 sec, to form the MOSFET. Besides, for the purpose of accelerating the dopant activation and suppressing diffusion, annealing may be carried out by spike RTA under the conditions of 1050° C. and 0 sec.

Next, Ni (nickel) is deposited in a thickness of 8 nm by sputtering. Then, RTA is conducted under the conditions of 350° C. and 30 sec, whereby silicidation (NiSi) is effected on the silicon substrate, followed by removal of unreacted Ni present on the field oxide films by H₂SO₄/H₂O₂.

Subsequently, RTA is conducted under the conditions of 500° C. and 30 sec, to form low-resistance NiSi. Incidentally, NiPtSi can also be formed through depositing NiPt. Other than these, silicide materials of cobalt, titanium or the like can also be adopted. In any of these cases, the RTA temperature can be set appropriately.

### <Semiconductor Device Manufacturing Method (No. 2)>

Now, a method of manufacturing a semiconductor device according to an embodiment of the present invention will be described below. FIGS. 9 to 11 are schematic sectional views for illustrating a semiconductor device manufacturing method (No. 2) according to this embodiment. Description will be made following the sequence of steps. The steps up to the gate electrode forming step (FIG. 4) are common for this manufacturing method (No. 2) and the above-described manufacturing method (No. 1), and, therefore, the subsequent steps will be described below.

(A) Gate Insulator Film Retreating Step (FIG. 9)

In order to retreat the high dielectric constant gate insulator films 110 under the gate electrodes 120, the high dielectric constant gate insulator films 110 are subjected to wet etching by use of a hydrofluoric acid solution. The retreating amount on each side is several tens of nanometers.

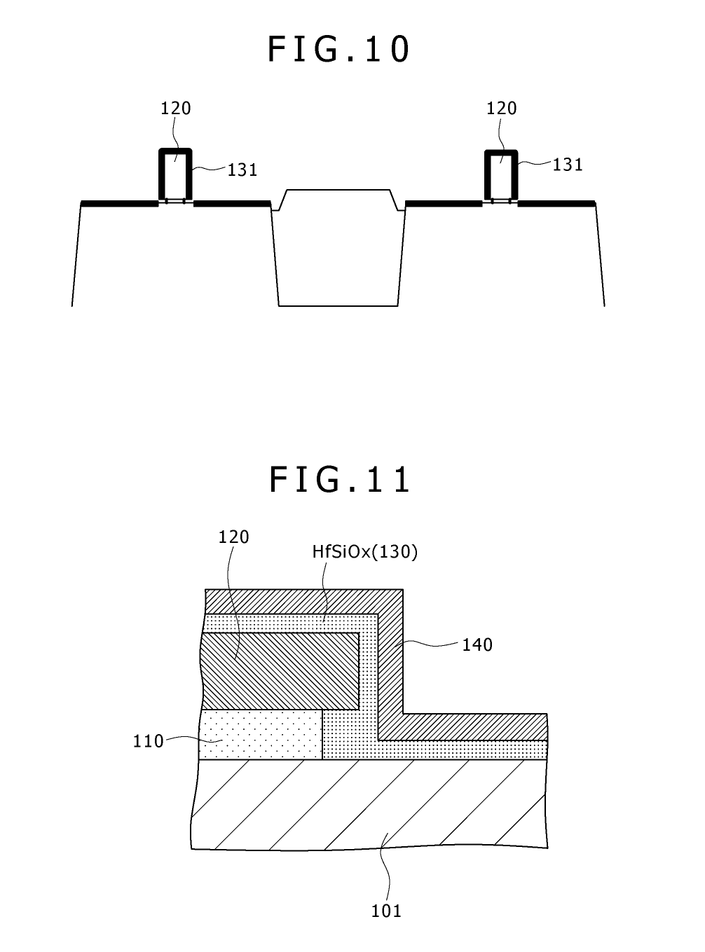

(B) High Dielectric Constant Material Film Forming Step (FIG. 10)

Subsequently, a material, for instance hafnium 131, for forming a layer of a high dielectric constant material over the whole surface is deposited in a quantity of 5×10¹³ atoms/cm² by PVD. Here, the gate electrodes 120 serves as eaves, so that it possible to regulate the amount of the material deposited on the sides of the high dielectric constant gate insulator films 110, and to obviate direct action of plasma damages at the time of film formation on the gate edges. Next, annealing is conducted in an NH₃ atmosphere, thereby increasing the bonding strength between hafnium 131 and the high dielectric constant gate insulator films 110.

The subsequent steps, specifically, the offset film formation and subsequent steps in the above-described manufacturing method (No. 1) are common for the MOSFET forming step shown in FIG. 6 and the MOSFET forming and silicide forming step shown in FIG. 8.

FIG. 11 is a schematic sectional view for illustrating a major part of the structure of the semiconductor device manufactured by the manufacturing method (No. 2). Prior to the formation of HfSiOx as the protective films 130 of the high dielectric constant material at the sides of the gate electrodes 120, end parts of the high dielectric constant gate insulator films 110 under the gate electrodes 120 are retreated by the etching, so that the gate electrodes 120 in these areas are provided with eaves.

When a layer of hafnium for forming a high dielectric constant material is formed under this condition, hafnium is thickly deposited in the areas where the high dielectric constant gate insulator films 110 are retreated, and, when hafnium is oxidized in the subsequent step to form HfSiOx (protective films 130) as the high dielectric constant material, these portions can be enhanced in compositional ratio, while the other portions can be lowered in compositional ratio. This ensures that diffusion of oxygen from the sides of the high dielectric constant gate insulator films 110 can be effectively prevented, and a configuration can be realized in which the high dielectric constant material is not left in the areas where the high dielectric constant material is unnecessary (the areas on the gate electrodes 120 and on the Si substrate 101).

### <Effects of the Embodiments>

According to the embodiments as above, the metal formed at the sides of the gates for forming a high dielectric constant material is converted into the high dielectric constant material though diffusion of oxygen in the subsequent step, so that oxygen would not reach the ends of the gate insulator films. Therefore, it is possible to prevent variations in characteristics such as a change in the EOT at the gate ends.

In addition, since the nitride film for blocking oxygen in the related art is not used in these embodiments, digging of the substrate due to processing of such a nitride film is obviated. Besides, since the sputtered metal is converted into the high dielectric constant material through oxidation, electrical conduction between the gates and the source/drain extension regions can be obviated.

Furthermore, by retreating the gate insulating films to the inner sides relative to the gate electrodes, it is possible to realize a change in composition between the portions beside the gate insulator films and the portions on the silicon substrate. Accordingly, it is possible to meet the demand for a high dielectric constant material composition for suppressing the diffusion of oxygen into the gate insulator films (the demand for increasing a compositional ratio) and to simultaneously meet the demand for eventually eliminating the high dielectric constant material present on the silicon substrate (the demand for lowering a compositional ratio).

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a high dielectric constant gate insulator film provided on a semiconductor substrate;
a gate electrode formed on said high dielectric constant gate insulator film;
a protective film formed at side surfaces of said high dielectric constant gate insulator film and said gate electrode; and
a side wall material provided on the outside of said protective film,
wherein said protective film includes a high dielectric constant material having, in its composition, at least one metal selected from the group consisting of Hf, Zr, Al, La, Pr, Y, Ti, Ta and W.

2. The semiconductor device as set forth in claim 1,
wherein the concentration of said metal is in the range of from 1×10¹³ atoms/cm², inclusive, to 1×10¹⁵ atoms/cm², exclusive.

3. The semiconductor device as set forth in claim 1,
wherein side ends of said high dielectric constant gate insulator film are provided on the inner side relative to side ends of said gate electrode, and the thickness of said protective film at said side surfaces of said high dielectric constant gate insulator film is greater than the thickness of said protective film at said side surfaces of said gate electrode.

4. A method of manufacturing a semiconductor device, comprising the steps of:
forming a high dielectric constant gate insulator film and a gate electrode with predetermined lengths on a semiconductor substrate;
forming a protective film containing at least one metal selected from the group consisting of Hf, Zr, Al, La, Pr, Y, Ti, Ta and W, at side surfaces of said high dielectric constant gate insulator film and said gate electrode;
depositing a side wall material on the outside of said protective film and simultaneously oxidizing said metal to convert said metal into a high dielectric constant material; and
etching said high dielectric constant material together with said oxide film to form a side wall including said side wall material at said side surfaces of said high dielectric constant gate insulator film and said gate electrode through said high dielectric constant material.

5. The method of manufacturing a semiconductor device as set forth in claim 4,
wherein after the formation of said high dielectric constant gate insulator film and said gate electrode, side ends of said high dielectric constant gate insulator film are processed to be on the inner side relative side ends of said gate electrode, and subsequently said high dielectric constant material is formed.
